(19) United States
(12) Patent Application Publication
(10) Pub. No.: US 2022/0393221 A1
(43) Pub. Date: Dec. 8, 2022

(54) BATTERY CAPACITY DIVIDING MECHANISM

(71) Applicant: ZHEJIANG HANGKE TECHNOLOGIES CO., LTD, Hangzhou (CN)

(72) Inventors: Hongyu SANG, Hangzhou (CN); Shunjin WU, Hangzhou (CN); Ji CAO, Hangzhou (CN); Zheng CAO, Hangzhou (CN)

(21) Appl. No.: 17/710,110

(22) Filed: Mar. 31, 2022

(30) Foreign Application Priority Data
Jun. 2, 2021 (CN) 202110613292.6
Jan. 10, 2022 (CN) 202210020621.0

(51) Int. Cl. H01M 10/04

(52) U.S. Cl. CPC H01M 10/0404

(57) ABSTRACT

A battery accommodating mechanism includes a bottom plate, a battery accommodating device, a pin plate assembly and a top plate assembly sequentially arranged from bottom to top. The battery accommodating device includes a battery tray and a tray bottom plate assembly and mounting holes and cooling fans. The top plate assembly includes a top plate, a guide shaft slidably connected to the linear bearing embedded in the mounting holes, a circuit board and a driving member driving the bottom plate of the tray to move up and down so that the electrodes of the batteries in the battery tray contact and separate from the pin plate assembly to form the batteries. The pin board assembly includes a mounting board with pins arranged on the bottom surface of the mounting board and electrically connected with the pin board circuit board. The invention improves the efficiency of capacity dividing.

### TECHNICAL FIELD

The invention relates to the technical field of battery testing, in particular to a battery capacity dividing mechanism.

### BACKGROUND

Since its invention, lithium-ion batteries have been widely used for their advantages of high energy density, long service life, light weight and low self-discharge. At present, lithium-ion batteries are mainly used in the fields of mobile electronic equipment, electric bicycles and electric vehicles.

In recent years, with the country's strong support for the new energy battery industry, lithium batteries and their related manufacturing industries have experienced unprecedented development. In this environment, the requirements for the quality and production efficiency of lithium batteries are becoming more and more stringent. Therefore, it is necessary to strengthen the control of each production process of battery production and improve the product quality and production efficiency of each production process. In the battery forming process, researchers often use spring clips to clip the batteries one by one. The efficiency is low and the pressure of the spring clips is inconsistent, which affects the performance parameters of the battery.

### SUMMARY OF THE INVENTION

In order to solve the above problems of the prior art, the present invention proposes a battery capacity dividing mechanism improving the efficiency of battery capacity dividing and being easy to operate without affecting battery performance parameters.

A battery capacity dividing mechanism according to the present invention is characterized in that it includes a bottom plate 100, a battery accommodating device, a pin plate assembly 400 and a top plate assembly 500 arranged in sequence from bottom to top, wherein:

The upper surface of the horizontally arranged bottom plate 100 is provided with a support platform for supporting the battery accommodating device;

The battery accommodating device includes a horizontally arranged tray bottom plate assembly 200 and a battery tray 300. The tray bottom plate assembly 200 disposed on the said support platform of the bottom plate 100 includes a tray bottom plate 210, a linear bearing 220 and a cooling fan 230. The tray bottom plate 210 is provided with a tray placement area 280 whose each of the four outer corners is provided with a mounting holes 260 penetrating the tray bottom plate 210, and the mounting hole 260 is embedded with a linear bearings 220; some heat dissipation holes 270 is provided in the tray placement area 280 each of which a heat dissipation fan 230 is embedded in to dissipate heat of the battery 700 in the battery tray 300 during the charging and discharging process; the battery tray 300 is movably arranged between the tray bottom plate 200 and the pin plate assembly 400, and the battery tray 300 is provided with a plurality of battery placement slots 310 for fixing batteries;

The top plate assembly 500 disposed above the battery accommodating device includes a horizontally disposed top plate 510, a guide shaft 520, a pin board circuit board 530, and a drive member 540 driving the tray bottom plate 210 to move up and down, wherein the top of the guide shaft 520 being fixedly connected with the top plate 510 while the lower part of that being slidably connected with the linear bearing 220; the driving member 540 is installed on the bottom of the top plate 510 while the lifting end of that is connected to the tray bottom plate assembly 200 to drive the tray bottom plate 210 to move up and down so that the electrodes of the batteries in the battery tray 300 contact and separate from the pin plate assembly 400; the main power connection terminal of the pin board circuit board 530 mounted on the top plate 510 is electrically connected to an external power supply while the sub-power transmission connection terminal of that is electrically connected to the power supply terminal of the pin board assembly 400 so that the external power supply is transferred and distributed to the pin board assembly 400;

The pin plate assembly 400 includes a pin mounting plate 410 mounted on the bottom surface of the top plate 510 and a plurality of sets of pins 420 fixed on the bottom surface of the pin mounting plate 410 and located right above the battery placement slot 310. Each set of the pins 420 corresponds to one of the battery placement slots 310 while the connection end of that is electrically connected to the sub-power transmission connection end of the pin board circuit board 530.

Preferably, the tray bottom plate assembly 200 further includes a limiting pillar 250 and two guide bars 240 arranged on the tray bottom plate 210 in parallel and spaced apart on opposite sides of the tray placement area 280; The battery tray 300 is slidably disposed on the tray bottom plate 210 between the two guide bars 240; the limit pillar 250 is disposed at the edge of the rear side of the upper surface of the tray bottom plate 210 to prevent the battery tray 300 from sliding out of the tray bottom plate 210 and position the battery tray 300.

Preferably, the driving member 540 selects one of vertically arranged air cylinders, hydraulic cylinders or electric telescopic rods.

Further, the driving member 540 is an air cylinder whose cylinder body is fixed on the top plate 510, and the telescopic end of that is fixed on the tray bottom plate 210.

Preferably, the top plate assembly 500 further includes a positioning dowel 550 vertically disposed on the bottom surface of the top plate 510, and the battery tray 300 is provided with the positioning hole 320 corresponding to the positioning dowel 550.

Preferably, the pin plate assembly 400 further includes a guide plate 430 fixed on the bottom surface of the pin mounting plate 410. The pins 420 is fixed on the central axis of the guide groove 440 provided on the guide plate 430; the lower end of the guide groove 440 has a flared opening that gradually expands from top to bottom providing fine-tuning of the position of the battery 700 to eliminate the influence of assembly errors and component size errors and align battery 700 with pin 420 when the battery 700 approaches pin 420.

Preferably, the battery dividing mechanism further includes a smoke alarm 600 arranged on the top plate 510.

The use process of the invention is as follows: take out the battery tray, place the battery vertically in the battery placement slot of the battery tray, then place the battery tray on the tray placement area of the tray bottom plate, further start the driving member, and drive the battery on the tray bottom plate through the driving member. The battery tray rises so that the electrode of the battery contact the pin, and the pin provides current and voltage to the battery to realize battery activation and constant current and constant voltage charging. The mechanism divides the capacity of a large number of batteries at the same time. The capacity dividing efficiency is high while the heat dissipation fan provided on the tray bottom plate assembly effectively cool down the divided batteries.

The beneficial effects of the present invention are: the structure of the battery dividing mechanism is simple and reliable; the battery tray with the battery placed on the tray bottom plate is driven to move by the driving member so that the electrode of the battery contact the pin so as to realize the activation and constant current and constant voltage charging of the batteries, screening batteries according to capacity, and grading the batteries. The mechanism can divide the capacity of a large number of batteries at the same time, and the capacity dividing efficiency is high, and the heat dissipation fan provided on the tray bottom plate assembly can effectively dissipate the heat of the divided batteries.

### DESCRIPTION OF DRAWINGS

FIG. 1 is a front view of the overall structure of a battery dividing mechanism according to an embodiment of the present invention;

FIG. 2 is a perspective view of the overall structure of the battery dividing mechanism according to an embodiment of the present invention;

FIG. 3 is a top view of a tray bottom plate assembly of a battery dividing mechanism according to an embodiment of the present invention;

FIG. 4 is a front view of a needle plate assembly of a battery dividing mechanism according to an embodiment of the present invention;

FIG. 5 is a bottom view of a needle plate assembly of a battery dividing mechanism according to an embodiment of the present invention;

FIG. 6 is a perspective view of a top plate assembly of a battery dividing mechanism according to an embodiment of the present invention;

FIG. 7 is a front view of the needle plate assembly of the battery dividing mechanism according to an embodiment of the present invention;

FIG. 8 is a plan view of a battery tray of a battery separating mechanism according to an embodiment of the present invention.

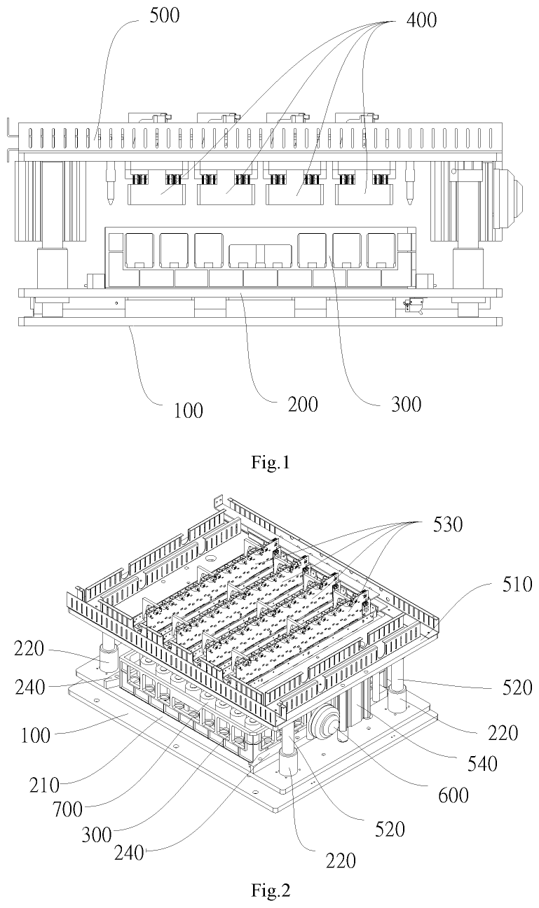

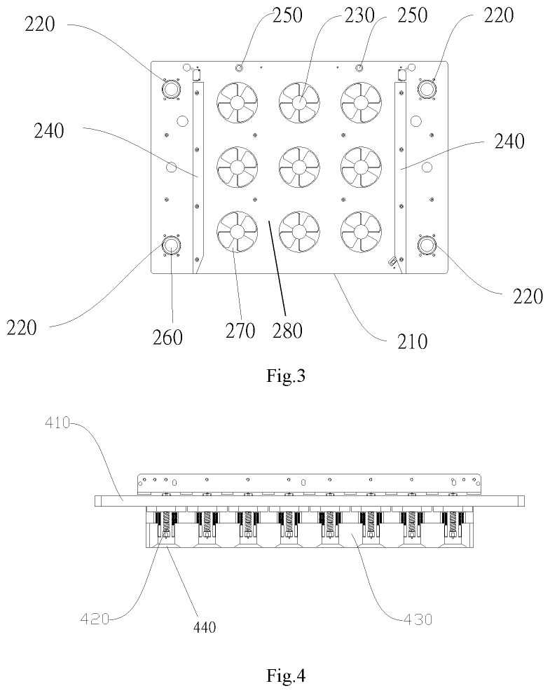

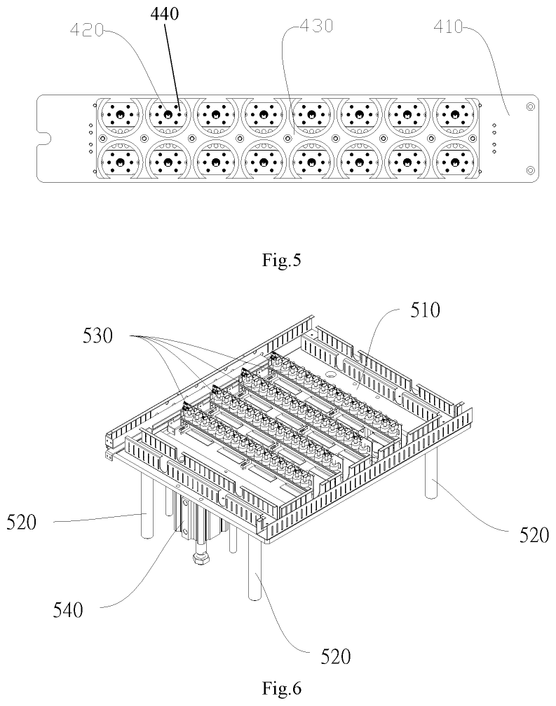

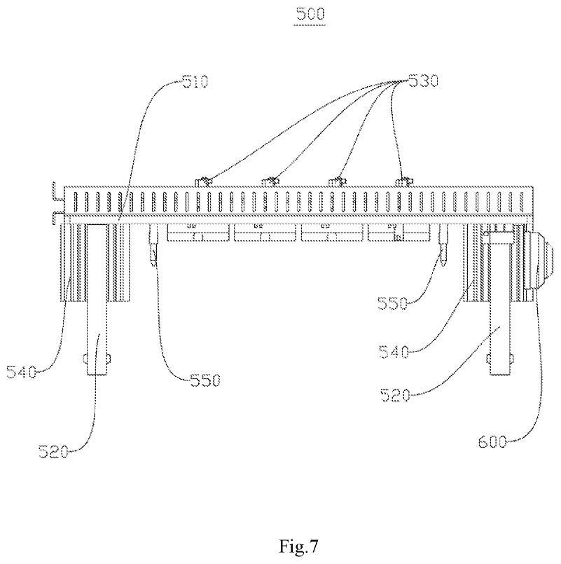

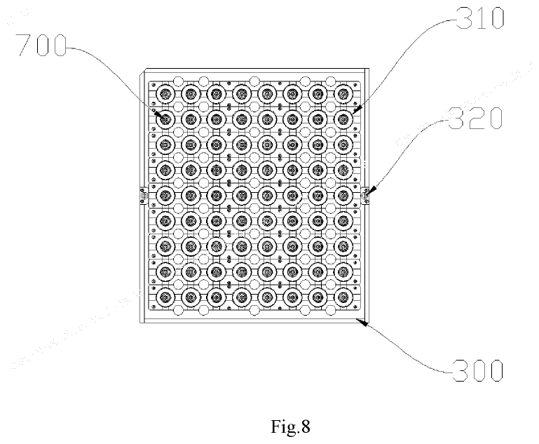

### EMBODIMENT

The present invention will be further described below in conjunction with the accompanying drawings.

A battery capacity dividing mechanism according to the present invention is characterized in that it includes a bottom plate 100, a battery accommodating device, a pin plate assembly 400 and a top plate assembly 500 arranged in sequence from bottom to top, wherein:

The upper surface of the horizontally arranged bottom plate 100 is provided with a support platform for supporting the battery accommodating device;

The battery accommodating device includes a horizontally arranged tray bottom plate assembly 200 and a battery tray 300. The tray bottom plate assembly 200 disposed on the said support platform of the bottom plate 100 includes a tray bottom plate 210, a linear bearing 220 and a cooling fan 230. The tray bottom plate 210 is provided with a tray placement area 280 each of the four outer corners of which is provided with a mounting holes 260 penetrating the tray bottom plate 210, and the mounting hole 260 is embedded with a linear bearings 220; some heat dissipation holes 270 is provided in the tray placement area 280 each of which a heat dissipation fan 230 is embedded in to dissipate heat of the battery 700 in the battery tray 300 during the charging and discharging process; the battery tray 300 is movably arranged between the tray bottom plate 200 and the pin plate assembly 400, and the battery tray 300 is provided with a plurality of battery placement slots 310 for fixing batteries;

The top plate assembly 500 disposed above the battery accommodating device includes a horizontally disposed top plate 510, a guide shaft 520, a pin board circuit board 530, and a drive member 540 driving the tray bottom plate 210 to move up and down, wherein the top of the guide shaft 520 being fixedly connected with the top plate 510 while the lower part of that being slidably connected with the linear bearing 220; the driving member 540 is installed on the bottom of the top plate 510 while the lifting end of that is connected to the tray bottom plate assembly 200 to drive the tray bottom plate 210 to move up and down so that the electrodes of the batteries in the battery tray 300 contact and separate from the pin plate assembly 400; the pin board circuit board 530 is mounted on the top plate 510, and the main power connection terminal of the pin board circuit board 530 is electrically connected to an external power supply while the sub-power transmission connection terminal of that is electrically connected to the power supply terminal of the pin board assembly 400 so that the external power supply is transferred and distributed to the pin board assembly 400;

The pin plate assembly 400 includes a pin mounting plate 410 mounted on the bottom surface of the top plate 510 and a plurality of sets of pins 420 fixed on the bottom surface of the pin mounting plate 410 and located right above the battery placement slot 310. Each set of the pins 420 corresponds to one of the battery placement slots 310 while the connection end of that is electrically connected to the sub-power transmission connection end of the pin board circuit board 530.

Preferably, the tray bottom plate assembly 200 further includes a limiting pillar 250 and two guide bars 240 arranged on the upper surface of the tray bottom plate 210 in parallel and spaced apart on opposite sides of the tray placement area 280; The battery tray 300 is slidably disposed on the tray bottom plate 210 between the two guide bars 240; the limit pillar 250 is disposed at the edge of the rear side of the upper surface of the tray bottom plate 210 to prevent the battery tray 300 from sliding out of the tray bottom plate 210 and position the battery tray 300.

The guide bars 240 are provided to guide the battery tray 300 when it is fed into the tray bottom plate 210. The limit pillar 250 prevents the battery tray 300 from sliding out from the tray bottom plate 210. The limit pillar 250 also plays a positioning role. When the battery tray 300 is placed on the tray bottom plate 210 and touches the limit pillar 250, it means that the battery tray 300 is installed in place.

The driving member 540 selects one of vertically arranged air cylinders, hydraulic cylinders or electric telescopic rods.

When the driving member 540 is an air cylinder, the cylinder body of the air cylinder is fixed on the top plate 510, and the telescopic end of the air cylinder is fixed on the tray bottom plate 210.

Preferably, the top plate assembly 500 further includes a positioning dowel 550 vertically disposed on the bottom surface of the top plate 510, and the battery tray 300 is provided with the positioning hole 320 corresponding to the positioning dowel 550. By setting the positioning dowels 550 to cooperate with the positioning holes 320 on the battery tray 300, it is further ensured that the pins 420 are in one-to-one contact with each batteries 700 when the capacity of batteries is divided.

Preferably, the pin plate assembly 400 further includes a guide plate 430 fixed on the bottom surface of the pin mounting plate 410. The pins 420 is fixed on the central axis of the guide groove 440 provided on the guide plate 430; the lower end of the guide groove 440 has a flared opening that gradually expands from top to bottom providing fine-tuning of the position of the battery 700 to eliminate the influence of assembly errors and component size errors and align battery 700 with pin 420 when the battery 700 approaches pin 420. By setting the guide plate 430, the battery 700 is positioned during the contacting process between the battery 700 and the pin 420, so that the battery 700 can precisely contact the pin 420.

The battery separating mechanism of the present invention further includes a smoke alarm 600 arranged on the top plate 510 to provide safety protection and prevent the fire for the mechanism during operation.

The content described in the embodiments of the present specification is merely an enumeration of the realization forms of the inventive concept, and the protection scope of the present invention should not be regarded as limited to the specific forms stated in the embodiments, and the protection scope of the present invention also includes equivalent technical means conceivable by those skilled in the art according to the inventive concept.

1. A battery capacity dividing mechanism according to the present invention is characterized in that it includes a bottom plate (100), a battery accommodating device, a pin plate assembly (400) and a top plate assembly (500) arranged in sequence from bottom to top, wherein:
The upper surface of the horizontally arranged bottom plate (100) is provided with a support platform for supporting the battery accommodating device;
The battery accommodating device includes a horizontally arranged tray bottom plate assembly (200) and a battery tray (300). The tray bottom plate assembly (200) disposed on the said support platform of the bottom plate (100) includes a tray bottom plate (210), a linear bearing (220) and a cooling fan (230). The tray bottom plate (210) is provided with a tray placement area (280) whose each of the four outer corners is provided with a mounting holes (260) penetrating the tray bottom plate (210), and the mounting hole (260) is embedded with a linear bearings (220); some heat dissipation holes (270) is provided in the tray placement area (280) each of which a heat dissipation fan (230) is embedded in to dissipate heat of the battery (700) in the battery tray (300) during the charging and discharging process; the battery tray (300) is movably arranged between the tray bottom plate (200) and the pin plate assembly (400), and the battery tray (300) is provided with a plurality of battery placement slots (310) for fixing batteries;
The top plate assembly (500) disposed above the battery accommodating device includes a horizontally disposed top plate (510), a guide shaft (520), a pin board circuit board (530), and a drive member (540) driving the tray bottom plate (210) to move up and down, wherein the top of the guide shaft (520) being fixedly connected with the top plate (510) while the lower part of that being slidably connected with the linear bearing (220); the driving member (540) is installed on the bottom of the top plate (510) while the lifting end of that is connected to the tray bottom plate assembly (200) to drive the tray bottom plate (210) to move up and down so that the electrodes of the batteries in the battery tray (300) contact and separate from the pin plate assembly (400); the main power connection terminal of the pin board circuit board (530) mounted on the top plate (510) is electrically connected to an external power supply while the sub-power transmission connection terminal of that is electrically connected to the power supply terminal of the pin board assembly (400) so that the external power supply is transferred and distributed to the pin board assembly (400);
The pin plate assembly (400) includes a pin mounting plate (410) mounted on the bottom surface of the top plate (510) and a plurality of sets of pins (420) fixed on the bottom surface of the pin mounting plate (410) and located right above the battery placement slot (310). Each set of the pins (420) corresponds to one of the battery placement slots (310) while the connection end of that is electrically connected to the sub-power transmission connection end of the pin board circuit board (530).

2. The battery capacity dividing mechanism according to claim 1, characterized in that: the tray bottom plate assembly (200) further includes a limiting pillar (250) and two guide bars (240) arranged on the tray bottom plate (210) in parallel and spaced apart on opposite sides of the tray placement area (280); The battery tray (300) is slidably disposed on the tray bottom plate (210) between the two guide bars (240); the limit (250) is disposed at the edge of the rear side of the upper surface of the tray bottom plate (210) to prevent the battery tray (300) from sliding out of the tray bottom plate (210) and position the battery tray (300).

3. A battery capacity dividing mechanism according to claim 1, characterized in that: the driving member (540) selects one of vertically arranged air cylinders, hydraulic cylinders or electric telescopic rods.

4. A battery capacity dividing mechanism according to claim 3, characterized in that: the driving member (540) is an air cylinder whose cylinder body is fixed on the top plate (510), and the telescopic end of that is fixed on the tray bottom plate (210).

5. The battery capacity dividing mechanism according to claim 1, characterized in that: the top plate assembly (500) further includes a positioning dowel (550) vertically disposed on the bottom surface of the top plate (510), and the battery tray (300) is provided with the positioning hole (320) corresponding to the positioning dowel (550).

6. The battery capacity dividing mechanism according to claim 1, characterized in that: the pin plate assembly (400) further includes a guide plate (430) fixed on the bottom surface of the pin mounting plate (410); the pins (420) is fixed on the central axis of the guide groove (440) provided on the guide plate (430); the lower end of the guide groove (440) has a flared opening that gradually expands from top to bottom providing fine-tuning of the position of the battery (700) to eliminate the influence of assembly errors and component size errors and align battery (700) with pin (420) when the battery (700) approaches pin (420).

7. The battery capacity dividing mechanism according to claim 1, characterized in that: the battery dividing mechanism further includes a smoke alarm (600) arranged on the top plate (510).
